(19) United States
(12) Patent Application Publication
(10) Pub. No.: US 2008/0079453 A1
(43) Pub. Date: Apr. 3, 2008

(54) Manufacture Method Of Vertical-Type Electric Contactor Vertical-Type Electric Contactor Thereof

(76) Inventor: Oug-Ki Lee, Seoul (KR)

Correspondence Address: JENKINS, WILSON, TAYLOR & HUNT, P. A., 3100 TOWER BLVD., Suite 1200, DURHAM, NC, 27707, US

(21) Appl. No.: 11/662,993

(22) PCT Filed: Sep. 20, 2005
(86) PCT No.: PCT/KR05/03114

§ 371 Date: Mar. 15, 2007

(30) Foreign Application Priority Data
Sep. 22, 2004 (KR) 10-2004-0075747

(51) Int. Cl. G01R 31/02; B44C 1/22

(52) U.S. Cl. 324/762; 216/11

(57) ABSTRACT

A method for fabricating a vertical-type electric contactor includes forming a first passivation pattern on a sacrificial substrate for forming at least one tip; performing an etch process, using the first passivation pattern as an etch mask, to form a trench in the sacrificial substrate; removing the first passivation pattern and forming a second passivation pattern to offer a space for forming a support beam, wherein the tip is merged with one end of the support beam; filling the trench and the space with a conductive material to form a tip and a support beam; forming a third passivation pattern on a sacrificial substrate including the tip and the support beam to offer a space for forming a hollow body; filling the space offered by the third passivation pattern with a conductive material to form a hollow body; bonding the hollow body with a bump formed on a micro-probe head (MPH); and removing the sacrificial substrate to open a tip of an electric contactor.

### TECHNICAL FIELD

The present invention relates to a method for manufacturing a vertical-type electric contactor and a vertical-type electric contactor manufactured thereby. More specifically, the present invention is directed to a method for manufacturing a vertical-type electric contactor including at least one support beam and a tip, which are merged into a column-shaped body to effectively remove an oxide layer of a test pad, for achieving an accurate test and a vertical-type electric contactor manufactured thereby.

### BACKGROUND ART

A semiconductor manufacturing process includes arranging a plurality of chips on a silicon wafer, packaging the arranged chips, and cutting the packaged chips into individual chips. To package and cut the chips arranged on the silicon wafer, it is necessary that an electrical signal is applied to the respective chips to check whether they operate normally, which is called a semiconductor test process. The test process is conducted using a probe card which has a contactor to correspond to a plurality of chips arranged on a silicon wafer. When the contactor contacts a chip arranged on the silicon wafer, an electrical signal is applied to check whether the chip operates normally.

A conventional needle-type electric contactor includes a plurality of needles. A tip is formed at one end of the respective needles. After the needles are bent and located at their determined positions, they are fixed to a fixture using epoxy and soldered to a printed circuit board (PCB). An electric contactor needs a predetermined elastic force for stably contacting a contact pad of a semiconductor integrated circuit. Unfortunately, iterative use of such a needle-type electric contactor results in deformation thereof or deterioration in horizontal degree and position accuracy thereof. Moreover, the needle-type electric contactor occupies a large space, which leads to difficulty in coping with a pitch between highly integrated circuits and gives rise to interrupt between signals through the needles to frustrate an accurate test.

Meanwhile, cantilever-type electric contactors have been suggested to overcome the foregoing disadvantages of needle-type electric contactors. A cantilever-type electric contactor is fabricated by vertically forming a bump on a substrate, forming a tip and a support beam contacting the tip on a sacrificial substrate to bond an upper end of the bump with one end of the support beam, and removing the sacrificial substrate. Cantilever-type electric contactors have been used to test highly integrated semiconductor devices.

### DISCLOSURE

### Technical Problem

Exemplary embodiments of the invention are directed to a method of manufacturing a vertical-type electric contactor and a vertical-type electric contactor manufactured thereby.

### Technical Solution

In an exemplary embodiment of the invention, the method may include forming a first passivation pattern on a sacrificial substrate for forming at least one tip; performing an etch process, using the first passivation pattern as an etch mask, to form a trench in the sacrificial substrate; removing the first passivation pattern and forming a second passivation pattern to offer a space for forming a support beam, wherein the tip is merged with one end of the support beam; filling the trench and the space with a conductive material to form a tip and a support beam; forming a third passivation pattern on a sacrificial substrate including the tip and the support beam to offer a space for forming a hollow body; filling the space offered by the third passivation pattern with a conductive material to form a hollow body; bonding the hollow body with a bump formed on a micro-probe head (MPH); and removing the sacrificial substrate to open a tip of an electric contactor.

In another exemplary embodiment of the invention, the method may include forming a first passivation pattern on a sacrificial substrate for forming at least one tip; performing an etch process, using the first passivation pattern as an etch mask, to form a trench in the sacrificial substrate; removing the first passivation pattern and forming a second passivation pattern on the sacrificial substrate to offer a space for forming a support beam, wherein the tip is merged with one end of the support beam; filling the trench and the space offered by the second passivation pattern with a conductive material to form a tip and a support beam; forming a third passivation pattern on a micro-probe head (MPH) to offer a space for forming a bump; filling the space offered by the third passivation pattern with a conductive material to form a bump; forming a fourth passivation pattern on the MPH including the bump to offer a space for forming a hollow body; filling the space offered by the fourth passivation pattern with a conductive material to form a hollow body; bonding the support beam with the hollow body; and removing the sacrificial substrate to open a tip of an electric contactor.

In another exemplary embodiment of the invention, the vertical-type electric contactor may include a micro-probe head (MPH) including at least one connecting terminal and interconnection for receiving an external signal; a bump disposed on the connecting terminal of the MPH; a column-shaped body vertically bonded with the bump; at least one support beam spaced apart from an opposite surface of the bottom end of the body; and a tip merged with the support beam.

### Advantageous Effects

The present invention is advantageous in fine pitches of highly integrated semiconductor devices. Due to the improved shape of a support beam, the contact performance with a contact pad of a semiconductor device is enhanced.

Further, the support beam is structurally tapered or bent to enhance an elastic force. Thus, the breakage probability of the support beam during a test is lowered to extend a lifespan thereof.

Further, a plurality of beam parts are provided to a hollow body. Thus, many scratches are produced during the test of a semiconductor device to effectively punch an oxide layer.

Further, the support beam is structurally tapered or bent to distribute a stress concentration resulting from an external force applied to a tip.

Further, a connecting beam is provided between the support beam and the hollow body. Thus, a stress concentration resulting from an external force applied to a tip is distributed and sufficient overdrive (OD) is obtained.

Further, a plurality of beams are connected at different angles. Thus, a beam having a generally curved shape is realized to distribute a stress concentration resulting from an external force applied to a tip and to obtain sufficient overdrive (OD).

### DESCRIPTION OF DRAWINGS

FIG. 1 is a cross-sectional view of a method for manufacturing a vertical-type electric contactor according to the present invention.

FIG. 2 is a cross-sectional view of an alternative version of the method described with reference to FIG. 1.

FIG. 3 illustrates the use states of the vertical-type electric contactor manufactured by the method described with reference to FIG. 1 or FIG. 2.

FIG. 4 is a perspective view of a vertical-type electric contactor according to the present invention.

FIG. 5 is a perspective view of a modified version of the vertical-type electric contactor illustrated in FIG. 4.

FIG. 6 and FIG. 7 are cross-sectional views of a method for manufacturing a vertical-type electric contactor where a connecting beam is further installed at a body.

FIG. 8 is a cross-sectional view of an alternative version of the method described with reference to FIG. 6 and FIG. 7.

FIG. 9 illustrates the use state of a vertical-type electric contactor manufactured by the method described with reference to FIG. 6 and FIG. 7.

FIG. 10 is a perspective view of a vertical-type electric contactor where a connecting beam is further installed at a body.

FIG. 11 is a perspective view of a modified version of the vertical-type electric contactor illustrated in FIG. 10.

FIG. 12 is a cross-sectional view of a method for manufacturing a vertical-type electric contactor where a support beam is formed at the inner side of a body according to the present invention.

FIG. 13 is a cross-sectional view of an alternative version of the method described with reference to FIG. 12.

FIG. 14 illustrates the use state of a vertical-type electric contactor manufactured by the method described with reference to FIG. 12 or FIG. 13.

FIG. 15 is a perspective view of a vertical-type electric contactor where a support beam is installed at the inner side of a body according to the present invention.

FIG. 16 is a perspective view of a modified version of the vertical-type electric contactor illustrated in FIG. 15.

FIG. 17 and FIG. 18 are cross-sectional views of a method for manufacturing a vertical-type electric contactor where an incline beam is further installed at a body according to the present invention.

FIG. 19 illustrates the use state of a vertical-type electric contactor manufactured by the method described with reference to FIG. 17 and FIG. 18.

FIG. 20 is a perspective view of the vertical-type electric contact illustrated in FIG. 19.

FIG. 21 and FIG. 22 are cross-sectional views of a method for manufacturing a vertical-type electric contactor where a plurality of incline beams are connected with a body to realize a beam having a curved shape according to the present invention.

FIG. 23 illustrates the use state of the vertical-type electric contactor manufactured by the method described with reference to FIG. 21 and FIG. 22.

FIG. 24 is a perspective view of the vertical-type electric capacitor illustrated in FIG. 23.

### BEST MODE

### Embodiment 1

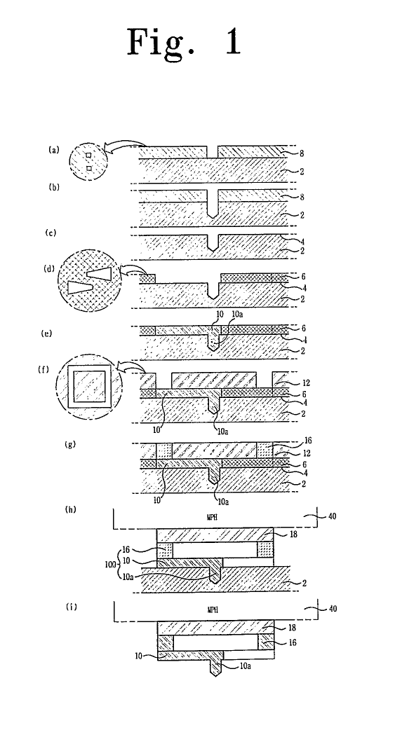

A method for manufacturing a vertical-type electric contactor according to a first embodiment of the present invention will now be described with reference to FIG. 1.

As illustrated in (a) of FIG. 1, a passivation layer (not shown) is formed on a sacrificial substrate having a predetermined Miller index, such as [100]. The passivation layer is made of oxide, and the sacrificial substrate is made of silicon. A second passivation pattern 8 is formed on the passivation layer to be used as an etch mask.

The formation of the first passivation pattern 8 is done by sequentially performing a photolithography process and an etch process. In the photolithography process, photoresist is coated on the sacrificial substrate 2 and the coated photoresist is exposed and developed.

As illustrated in (b) of FIG. 1, using the first passivation pattern 8 as an etch mask, a wet etch process and an anisotropic dry etch process are successively performed to form a trench in the sacrificial substrate 2. That is, the formation of the trench is done by forming a shallow trench corresponding to a tip end by means of a first wet etch and making the trench deeper by means of a second anisotropic dry etch. The trench is formed to collinearly align lateral ends of adjacent tips with each other while the lateral ends are spaced by a predetermined distance.

The trench corresponding to the tip end may have various shapes such as the cone shape and the pyramid shape. The dry etch process is a kind of deep trench etching implemented by reactive ion etching (RIE) that is called a Bosh process.

The first passivation pattern 8 is removed and a seed layer 4 is formed on the sacrificial substrate 2 by means of a sputtering process, as illustrated in (c) of FIG. 1. The seed layer 4 is made of copper (Cu) and serves as the seed of a subsequent plating process. Photoresist is coated on the seed layer 4 to a predetermined thickness. After the coated photoresist is exposed and developed, a second passivation pattern is formed to have a sectional pattern of a support beam, as illustrated in (d) of FIG. 1. As a result, a space is offered for forming a support beam by means of a subsequent filling process using metal material.

As illustrated in (e) of FIG. 1, a space and a trench opened by the second passivation pattern 6 are filled with conductive metal by means of plating. A planarization process (e.g., chemical mechanical polishing (CMP), etchback or grinding) is carried out to form a tip 10a and a support beam 10 spaced by a predetermined distance.

The tips 10a and the support beam 10 face each other. The respective tips 10a of the support beam 10 are spaced by a predetermined distance to face each other. The respective tips 10 are tapered along the tip 10a from an opposite side of the tip 10a, i.e., the support beam 10. While the two support beams 10 are illustrated, at least one support beam 10 may be formed. Further, the formation of the tip 10a and the support beam 10 may be done by means of chemical vapor deposition (CVD) or physical vapor deposition (PVD) as well as the plating.

As illustrated in (f) of FIG. 1, a third passivation pattern 12 is formed on the sacrificial substrate 2 including the tip 10a and the support beam 10 to form a space for forming a hollow body. The third passivation pattern 12 may be a square-shaped pattern having a sectional pattern of the hollow body, i.e., opening the end top surface of a support beam connected to the tip 10a. Also the formation of the third passivation pattern 12 is done by means of an exposing process and a developing process.

As illustrated in (g) of FIG. 1, the spaced formed by the third passivation pattern 12 is filled with conductive material by means of plating. A planarization process (e.g., CMP, etchback or grinding) is carried out to form a hollow body 16 having a square-column shape. The formation of the hollow body 16 may be done by means of CVD or PVD as well as the plating. The hollow body 16 may have various hollow column shapes such as the square-column shape, the cylinder shape, and the triangle-column shape according to manufacturers. Alternatively, a body having the inner-filled column shape may be formed instead of the hollow body 16.

As illustrated in (h) of FIG. 1, the second passivation pattern 6 and the third passivation pattern 12 are removed by means of a wet etch process. The hollow body 16 is bonded with a bump 18 formed at a contact terminal on a multi-layered printed circuit board, i.e., micro-probe head (hereinafter referred to as “MPH”) 40.

As illustrated in (i) of FIG. 1, the sacrificial substrate 2 is removed by means of a wet etch to fabricate an electric contactor 100 including an opened tip 10a, a support beam 10, and a hollow body 16.

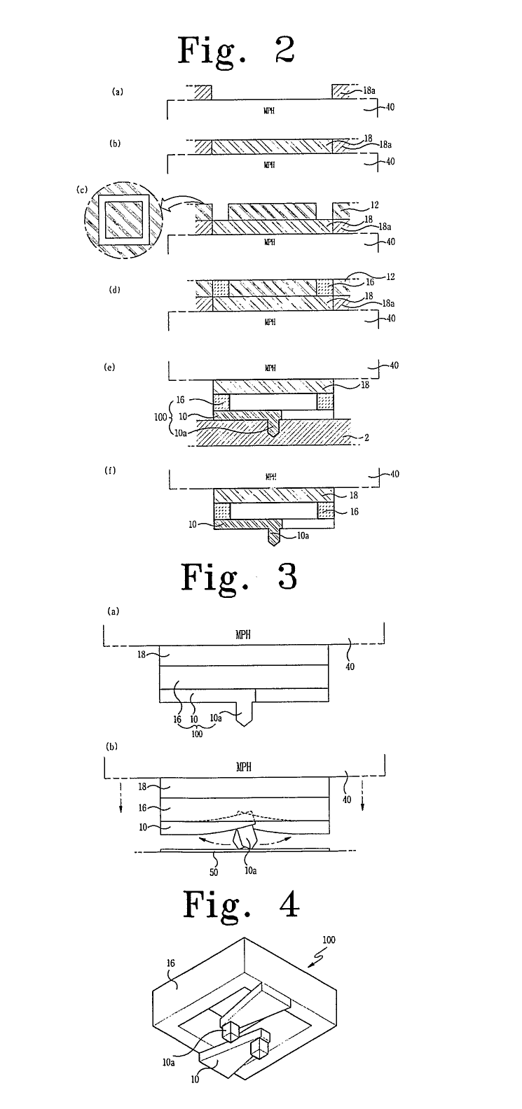

FIG. 2 illustrates an alternative method for fabricating the electric contactor of FIG. 1. According to the alternative method, a bump 18 is formed on an MPH 40. A hollow body 16 is formed on the bump 18. A support beam 10 merged with a tip 10a formed on a sacrificial substrate 2 is bonded with the hollow body 16 to fabricate an electric contactor. The elements designated by the same numerals in FIG. 1 have the same functions and operations and will not be described in further detail.

As illustrated in (a) of FIG. 2, a region of a contact terminal (not shown) formed on a multi-layered printed circuit board, i.e., MPH 40 is opened to form a first passivation pattern 18a having a space of a bump section shape. Thus, the space is offered for forming a bump.

As illustrated in (b) of FIG. 2, the space offered by the first passivation pattern 18 is filled with a conductive material by means of a plating process to form a bump 18.

As illustrated in (c) of FIG. 2, a third passivation pattern 12 having a section shape of a hollow body is formed on the MPH 40 where the bump 18 is formed. Thus, a space is offered for forming a hollow body.

As illustrated in (d) of FIG. 2, the space offered by the third passivation pattern 12 is filled with a conductive material by means of a plating process to form a hollow body 16.

As illustrated in (e) of FIG. 2, after performing the same processes as illustrated in (a) through (e) of FIG. 1, a support beam 10 where a second passivation pattern 6 is removed is bonded with the hollow body 16.

As illustrated in (f) of FIG. 2, the sacrificial substrate 2 is removed by means of a wet etch process to open a tip 10a and a support beam 10 of an electric contactor 100.

A vertical-type electric contactor having a hollow body of the embodiment described with reference to (a) through (i) of FIG. 1 and a vertical-type electric contactor having a hollow body of the embodiment described with reference to (a) through (f) of FIG. 2 will now be described below in detail.

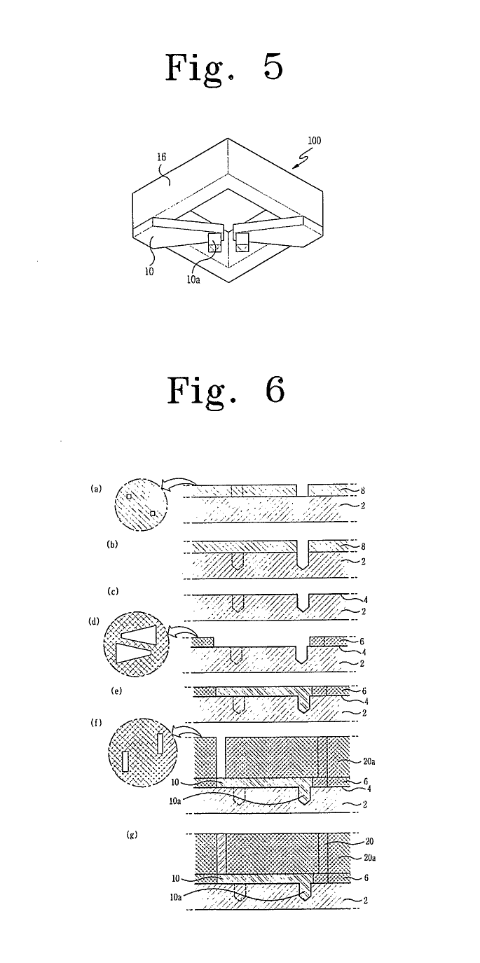

As described above, a vertical-type electric contactor having a hollow body according to the first embodiment includes a square-column-shaped hollow body 16 vertically bonded with a bump 18 formed below an MPH 40, at least one support beam 10 spaced apart from an opposite side to the lower side end of the hollow body 16, and a tip 10a merged with the support beam 10 such that the side end of the tip 10a is collinearly aligned with the side end of an adjacent tip, as illustrated in (a) of FIG. 3, FIG. 4, and FIG. 5.

In this embodiment, the support beam 10 merged with the tip 10a is disposed to be parallel with the end of a support beam 10 merged with another tip 10a. Each of the tips 10 is tapered along the tip 10a from an opposite side of the tip 10a, i.e., the support beam 10. The hollow body 16 may have various shapes such as the square-column shape, the cylinder shape, and the triangle-column shape. Alternatively, a body having an inner-filled cylinder shape may be formed instated of the hollow body 16.

During a test using the vertical-type electric contactor having the above-described hollow body, at least one tip 10a scratches a top surface of an electrode pad 50, while moving to the top outer side of the electrode pad 50 from the top inner side thereof, to further remove an oxide layer, as illustrated in (b) of FIG. 3. Thus, a contact area of the tip 10a is broadened to enhance the accuracy of the test. When the tip 10a is separated from the electrode pad 10a, the original position of the tip 10a is restored.

As illustrated in FIG. 4 and FIG. 5, one or more support beams 10 may be formed to be spaced from any position of the bottom end of the hollow body 16 to be spaced apart from each other. Especially referring to FIG. 5, a support beam 10 is connected with the bottom corner of the hollow body 16. Thus, the connecting area between the support beam 10 and the hollow body 16 is extended to effectively distribute a stress concentration that is present at a connecting portion therebetween.

### Embodiment 2

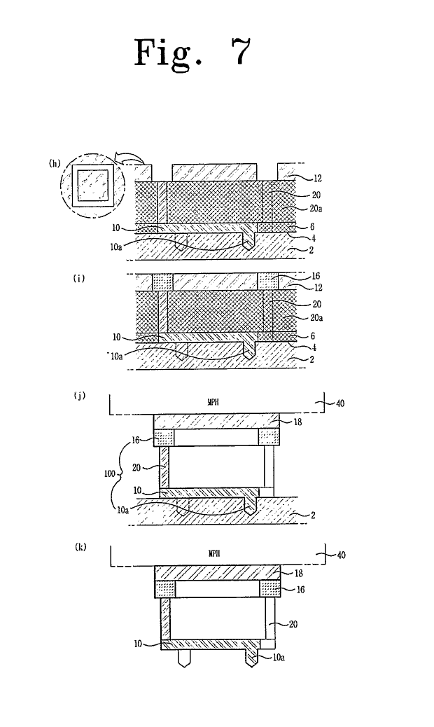

A method for fabricating a vertical-type electric contactor having a hollow body according to the second embodiment of the present invention will now be described with reference to FIG. 6 and FIG. 7. The same elements designated by the same numerals as in the first embodiment have the same functions and operations and will not be described in further detail.

As illustrated in (a) of FIG. 6, a first passivation pattern 8 is formed on a sacrificial substrate 2 having a determined directionality. The sacrificial substrate 2 is made of silicon.

As illustrated in (b) of FIG. 6, using the first passivation pattern 8 as a mask, a wet etch process and an anisotropic dry etch are successively performed to form trenches on the sacrificial substrate 2. The trench corresponds to a tip of an electric contactor. Unlike the first embodiment, the trenches are spaced at regular intervals. After removing the first passivation pattern 8, a seed layer 4 is formed on the sacrificial substrate 2 by means of a sputtering process, as illustrated in (c) of FIG. 6. The seed layer 4 may be made of copper (Cu) and serves as seed in a subsequent plating process.

After coating a photoresist thereon to a predetermined thickness, exposing and developing processes are performed to form a second passivation pattern 6 having a support beam section pattern, as illustrated in (d) of FIG. 6. Thus, a space is offered for forming a support beam by means of a subsequent filling process using a metal material.

As illustrated in (e) of FIG. 6, the space opened by the second passivation pattern 6 and the trench are filled with a conductive material by means of a plating process. Afterwards, a planarization process such as CMP, etchback or grinding is performed to form two support beams 10 spaced by a predetermined distance. Both ends of the support beams 10 are disposed at position to be inwardly spaced apart from the end of an adjacent support beam 10. The support beams 10 are merged with a tip 10a.

Although two support beams 10 spaced are illustrated in this embodiment, at least one support beam may be formed. Further, the formation of the tip 10a and the support beam 10 may be done by means of a CVD or PVD process as well as a plating process.

As illustrated in (f) of FIG. 6, a third passivation pattern 20a is formed on the sacrificial substrate 2 where the tip 10a and the support beam 10 are formed. The third passivation pattern 20a has a connecting beam section pattern. Thus, a space is offered for forming a connecting beam by means of a subsequent filling process using a metal material.

As illustrated in (g) of FIG. 6, the space opened by the third passivation pattern 20a is filled with a conductive material. Afterwards, a planarization process such as CMP, etchback or grinding is performed to form two connecting beams 20 vertically connected with the support beam 10.

As illustrated in (h) of FIG. 7, a fourth passivation pattern 12 is formed on the sacrificial substrate 2 where the connecting beam 20 is formed. The fourth passivation pattern 12 has a section shape of a hollow body, i.e., opens a top surface of the connecting beam 20. Thus, a space is offered for forming a hollow body.

As illustrated in (i) of FIG. 7, the space offered by the fourth passivation pattern 12 is filled with a conductive material by means of a plating process. Afterwards, a planarization process is performed to form a hollow body 16 having a square-column shape. The planarization process has been described previously and will not be described in further detail. The hollow body 16 may have various hollow column shapes such as the square-column shape, the cylinder shape, and the triangle-column shape according to manufacturers. Alternatively, a body having the inner-filled column shape may be formed instead of the hollow body 16.

As illustrated in (j) of FIG. 7, after removing second passivation pattern 6, the third passivation pattern 20a, and the fourth passivation pattern 12 stacked on the sacrificial substrate 2, the hollow body 16 is bonded with a bump 18 formed at a contact terminal (not shown) on a multi-layered printed circuit board, i.e., MPH 40.

As illustrated in (k) of FIG. 7, the sacrificial substrate 2 is removed by means of a wet etch process to open the tip 10a. As a result, an electric contactor 100 is fabricated. The electric contactor 100 includes a support beam 10 merged with the tip 10a such that both ends of the support beam 10 are disposed at position inwardly spaced from the end of an adjacent support beam 10, a connecting beam 20 vertically connected with the support beam 10, and a hollow body 16 with which the connecting beam 20 is bonded.

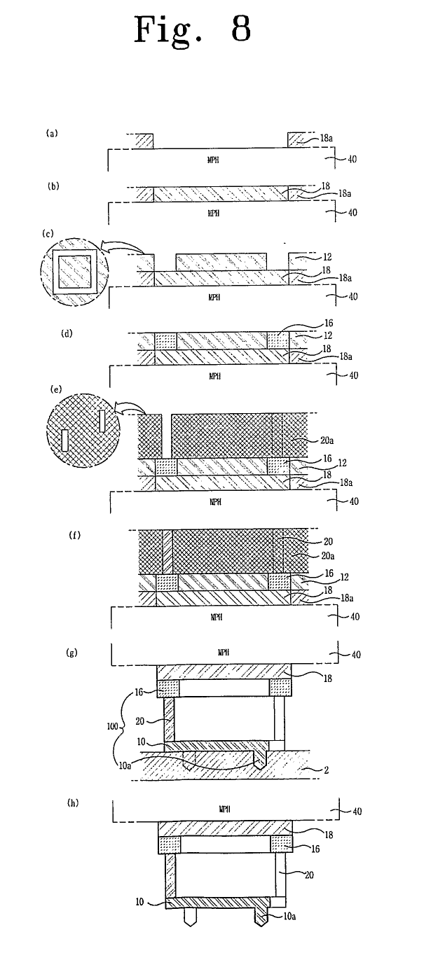

FIG. 8 illustrates an alternative method for fabricating the electric contactor 100. According to the alternative method, a support beam 10 is formed to be merged with the tip 10a. The support beam 10 is disposed such that both sides of the support beam 10 are disposed at position inwardly spaced from the end of an adjacent support beam 10. Afterwards, a bump 18, a hollow body 16, and a connecting beam 20 are sequentially formed below an MPH 40 to fabricate an electric contactor 100. The same elements designated by the same numerals in FIG. 6 and FIG. 7 have the same functions and operations and will not be described in further detail.

As illustrated in (a) of FIG. 8, a contact terminal (not shown) on a multi-layered printed circuit board, i.e, MPH 40 to form a first passivation pattern 18a having a bump section pattern.

As illustrated in (b) of FIG. 8, the space offered by the first passivation pattern 18a is filled with a conductive material by means of a plating process to form a bump 18.

As illustrated in (c) of FIG. 8, a second passivation pattern 12 is formed on the MPH 40. The second passivation pattern 12 has a section shape of a hollow body. Thus, a space is offered for forming a hollow body.

As illustrated in (d) of FIG. 8, the space offered by the second passivation pattern 12 is filled with a conductive material to form a hollow body 16. The hollow body 16 may have various hollow column shapes such as the square-column shape, the cylinder shape, and the triangle-column shape according to manufacturers. Alternatively, a body having the inner-filled column shape may be formed instead of the hollow body 16.

As illustrated in (e) of FIG. 8, a third passivation pattern 20a is formed on the bump 18. The third passivation pattern 20a has a connecting beam section pattern. Thus, a space is offered for forming a connecting beam 20.

As illustrated in (f) of FIG. 8, the space offered by the third passivation pattern 20a is filled with a conductive material to form a connecting beam 20. The connecting beam 20 is vertically connected with the hollow body 16.

As illustrated in (g) of FIG. 8, a support beam 10 where the second passivation pattern 12 is removed is bonded with a connecting beam 20 where the third passivation pattern 20a is removed, by means of the same processes as in (a) through (e) of FIG. 6.

As illustrated in (h) of FIG. 8, the sacrificial substrate 20 is removed to open a tip 10a of the electric contactor 100.

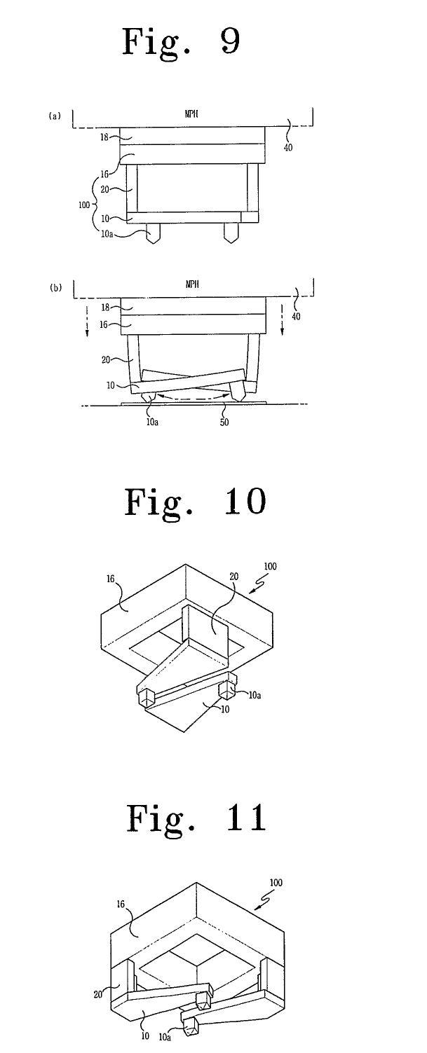

A vertical-type electric contactor having a hollow body, illustrated in FIG. 9, FIG. 10, and FIG. 11, are fabricated according to the embodiment described with reference to (a) through (k) of FIG. 6 and the embodiment described with reference to (a) through (h) of FIG. 8. The vertical-type electric contactor includes a square-column-shaped hollow body 16 vertically bonded with a bump 18 formed below an MPH 40, at least one connecting beam 20 vertically spaced from the bottom end of the hollow body 16, and a support beam 10 having one end where a tip 10a is formed and the other end to which the connecting beam 20 is vertically connected.

The support beam 10 merged with the tip 10a is spaced apart from another support beam 10 merged with another tip 10a to face each other. Each tip 10a of the support beam 10 is disposed at position inwardly spaced from the end of an opposite support beam 10. Each of the support beams 10 is tapered along the tip 10a from the opposite side of the tip 10a.

In the vertical-type electric contactor having the above-described hollow body, while an electrode pad 50 of a semiconductor device is pressurized, at least one tip 10a moves to the top outer side of the electrode pad 50 from the top inner side thereof to remove an oxide layer formed on the electrode pad 50, as illustrated in (b) of FIG. 9. A test range extends to the top of the electrode pad 50 as long as a distance between the tips 10a spaced. Thus, a test range between the tips 10a extends to achieve an accurate test. When a tip 10a is separated from the electrode pad 50, the original position of the tip 10a is restored.

As illustrated in FIG. 10 and FIG. 11, at least one connecting beam 20 is formed to be spaced from any position of the bottom end of the hollow body 16. Especially referring to FIG. 11, a connecting beam is connected with the bottom corner of the hollow body. Thus, the connecting area is extended to effectively distribute a stress concentrated on a connecting portion between the support beam 10 and the hollow body 16.

### Embodiment 3

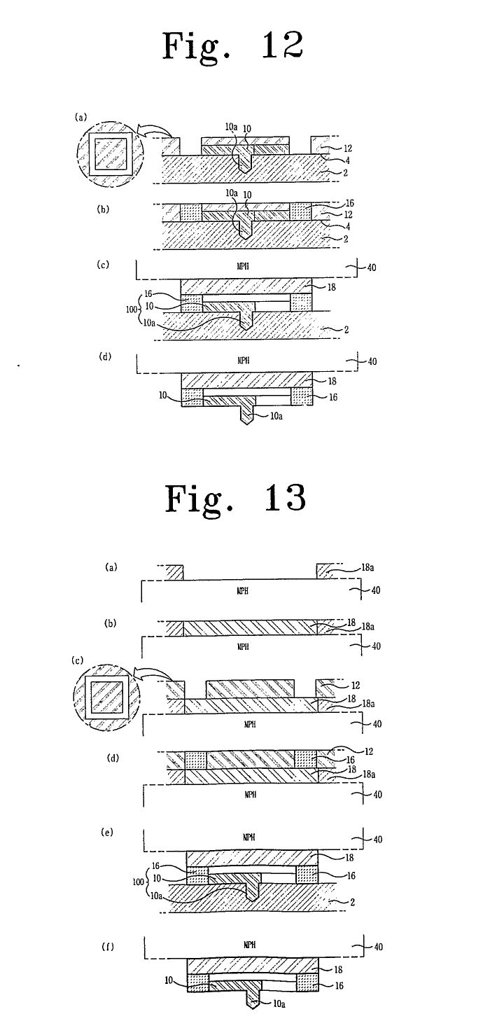

A method for fabricating a vertical-type electric contactor having a hollow body according to a third embodiment of the present invention will now be described more fully with reference FIG. 12. The same elements designated by the same numerals as in the first embodiment have the same functions and operations and will not be described in further detail.

Formation of a tip 10a and a support beam 10 is done by the same steps as described with reference to (a) through (e) of FIG. 1 and will not be described in further detail. Namely, after forming the tip 10a and the support beam 10 on a sacrificial substrate 2, a square-shaped first passivation pattern 12 is formed over the sacrificial substrate 2, as illustrated in (a) of FIG. 12. The first passivation pattern 12 has a section shape of a hollow body, i.e., opens a top surface of the sacrificial substrate 2. Thus, a space is offered for forming a hollow body.

As illustrated in (b) of FIG. 12, the space offered by the first passivation pattern 12 is filled with a conductive material by means of a plating process. Afterwards, a planarization process is carried out to form a hollow body 16 having a square-column shape. The support beam 10 is merged with an inner side section of the hollow body 16.

The planarization process has been described previously and will not be described in further detail. Also, alternative method for fabricating the hollow body 16 has been described previously and will not be described in further detail. The hollow body 16 may have various hollow column shapes such as the square-column shape, the cylinder shape, and the triangle-column shape according to manufacturers. Alternatively, a body having the inner-filled column shape may be formed instead of the hollow body 16.

As illustrated in (c) of FIG. 12, the first passivation pattern 12 for forming the support beam 10 and the hollow body 16 on the sacrificial substrate 2 is removed by means of a wet etch process. As previously described with reference to (i) of FIG. 1 in the first embodiment, the hollow body 16 is bonded with a bump 18 formed at a contact terminal (not shown) on an MPH 40.

As illustrated in (d) of FIG. 12, the sacrificial substrate 2 is removed by means of a wet etch process to fabricate an electric contactor 100 including the opened tip 10a, the support beam 10 merged with the tip 10a, and the hollow body 16 having an inner side where the support 10 is disposed.

FIG. 13 illustrates an alternative method for fabricating an electric contactor of FIG. 12. According to the alternative method, after forming a bump on an MPH 40, a hollow body is formed thereon. A support beam having a tip merged therewith is merged with an inner side section of the hollow body. Thus, an electric contactor is fabricated. The elements designated by the same numerals as in FIG. 12 have the same functions and operations and will not be described in further detail.

As illustrated in (a) of FIG. 13, a region of a contact terminal (not shown) on a multi-layered printed circuit board, i.e., MPH 40 is opened to form a first passivation pattern 18a having a bump section pattern. Thus, a space is offered for forming a bump.

As illustrated in (b) of FIG. 13, the space is filled with a conductive material by means of a plating process to form a bump 18.

As illustrated in (c) of FIG. 13, a second passivation pattern having a section shape of a hollow body is formed on the MPH 40 where the bump 18 is formed. Thus, a space is offered for forming a hollow body.

As illustrated in (d) of FIG. 13, the space offered by the second passivation pattern 12 is filled with a conductive material by means of a plating process to form a hollow body 16. The hollow body 16 may have various hollow column shapes such as the square-column shape, the cylinder shape, and the triangle-column shape according to manufacturers. Alternatively, a body having the inner-filled column shape may be formed instead of the hollow body 16.

As illustrated in (e) of FIG. 13, after removing the first and second passivation patterns 18a and 12, one end of the support beam 10 is fixedly bonded with an inner side section of the hollow body 16.

As illustrated in (f) of FIG. 13, a sacrificial substrate 2 is removed by means of a wet etch process to fabricate an electric contactor 100 including the opened tip 10a, the support beam 10 merged with the tip 10a, and the hollow body 16 having an inner side where the support 10 is disposed.

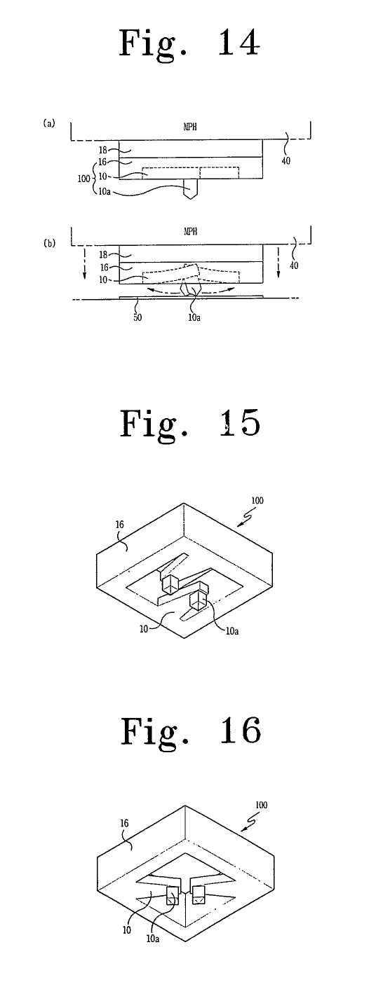

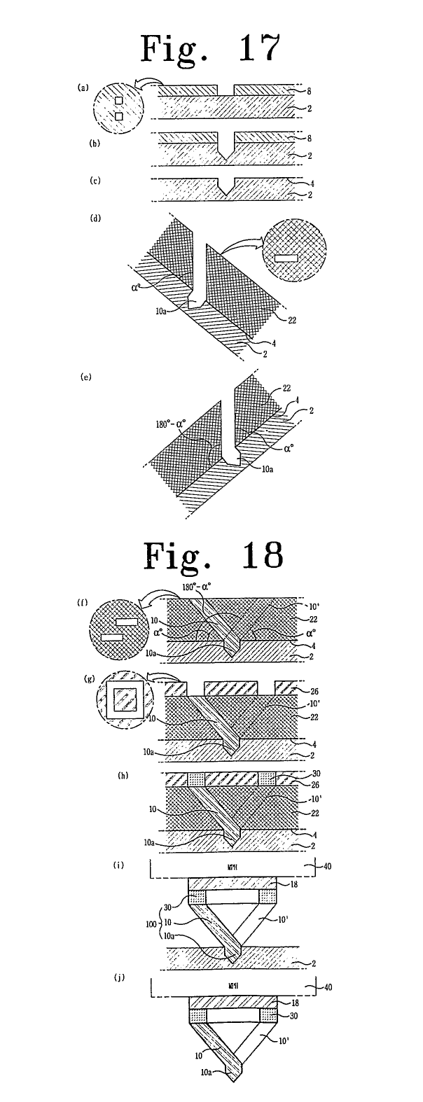

A vertical-type electric contactor having a hollow body, illustrated in FIG. 14, FIG. 15, and FIG. 16, includes a support beam 10 inserted into a hollow body 16 having a square-column shape. That is, one side end of the support beam 10 is bonded with an inner sidewall of the hollow body 16. Both side ends of a tip 10a are opposed to side ends of adjacent tips to be aligned collinearly.

In the vertical-type electric contactor having the above-described hollow body, while an electrode pad 50 of a semiconductor device is pressurized, at least one tip 10a moves to the top outer side of the electrode pad 50 from the top inner side thereof to remove an oxide layer within a predetermined range, as illustrated in of FIG. 14. Therefore, an accurate test may be achieved. A tip-formed end of the support beam 10 has a smaller width than an opposite end thereof. That is, the support beam 10 is tapered. The end having the larger width is connected with the hollow body 16, effectively distributing a stress concentration, resulting from the external force, which is present at a connecting portion between the support beam 10 and the hollow body 16 and sufficiently obtaining an overdrive (OD).

As illustrated in FIG. 15 and FIG. 16, at least one support beam 10 is merged with an inner section of the hollow body 16. Especially referring to FIG. 1, a connecting beam is connected with the bottom corner of the hollow body 16. Thus, the connecting area is extended to effectively distribute a stress concentrated on a connecting portion between the support beam 10 and the hollow body 16.

### Embodiment 4

A method for fabricating a vertical-type electric contactor having a hollow body according to a fourth embodiment of the present invention will now be described with reference to FIG. 17 and FIG. 18. The same elements designated by the same numerals as in the first embodiment have the same functions and operations and will not be described in further detail.

Formation of a trench for forming a tip 10a, illustrated in (a) through (c) of FIG. 17, is done by the same steps as described with reference to (a) through (c) of FIG. 1 and will not be described in further detail.

As illustrated in (d) of FIG. 17, a first passivation pattern 22 having an incline beam section pattern is formed on a sacrificial substrate 2 where a seed layer 4 is formed. The sacrificial substrate 2 is loaded on a wafer chuck of a typical inclined exposure apparatus. While the loaded sacrificial substrate 2 is inclined so that the space of an incline beam space has an angle of α° based on a top surface of the sacrificial substrate 2, exposing and developing processes are carried out to offer a space for forming an incline beam by a subsequent filling process using a metal material. Namely, the space of the incline beam is inclined at an angle of α° based on the top surface of the sacrificial substrate 2 and connected with one of tip-shaped trenches by exposing and developing the first passivation pattern. Thus, a space is offered for forming an incline beam by means of a subsequent filling process using a metal material.

As illustrated in (e) of FIG. 17, another incline beam 10′ is formed to be spaced apart from the incline beam 10. While the sacrificial substrate 2 is inclined so that the incline beam has an angle of 180-α° based on the top surface of the sacrificial substrate 2, exposing and developing processes are carried out to offer a space is offered for forming an incline beam by a subsequent filling process using a metal material.

As illustrated in (f) of FIG. 18, the space for forming a region opened by the first passivation pattern 22, i.e., incline beams 10 and 10′ and the trench for forming a tip 10a are filled with a conductive material by means of a plating process to form the incline beams 10 and 10′. The incline beams 10 and 10′ have angles of α° and 180-α° respectively and are spaced apart from each other. Connection portions between 10 and 10a and between 10′ and 10a are bent so that the end of each tip 10a vertically contacts a surface of a test object.

As illustrated in (g) of FIG. 18, a second passivation pattern 26 is formed on the sacrificial substrate 2. The second passivation pattern 26 has a section shape of a hollow body, i.e., opens end top surfaces of the incline beams 10 and 10′. Thus, a space is offered for forming a hollow body.

As illustrated in (h) of FIG. 18, the space offered by the second passivation pattern 26 is filled with a conductive material by means of a plating process. Afterwards, a planarization process is carried out to form a hollow body 30. The planarization process has been described previously and will not be described in further detail. The hollow body 30 may have various hollow column shapes such as the square-column shape, the cylinder shape, and the triangle-column shape according to manufacturers. Alternatively, a body having the inner-filled column shape may be formed instead of the hollow body 30.

As illustrated in (i) of FIG. 18, after removing the first and second passivation patterns 22 and 26 for forming an incline beam, the hollow body 30 is bonded with a bump 18 formed on an MPH 40.

As illustrated in (j) of FIG. 18, the sacrificial substrate 2 is removed by means of a wet etch process to fabricate an electric contactor 100 having the opened tip 10a and the incline beams 10 and 10′.

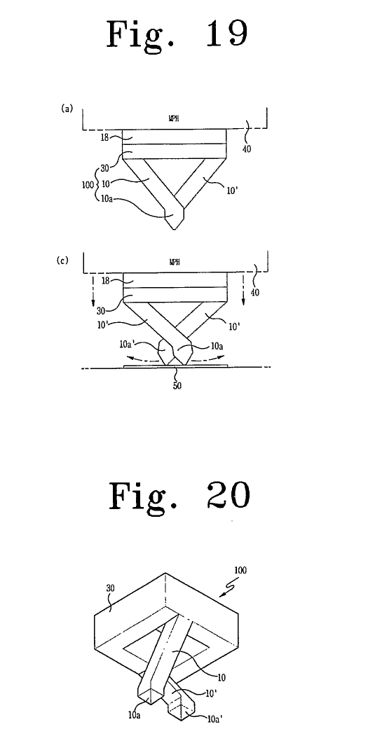

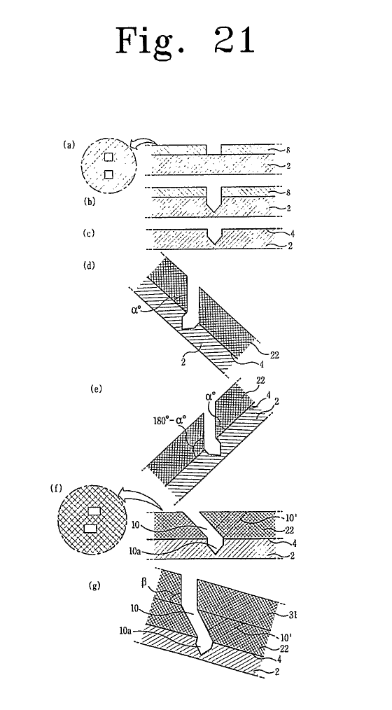

As illustrated in (a) of FIG. 19 and FIG. 20, the vertical-type electric contactor 100 fabricated by the method described with reference to FIG. 17 and FIG. 18 includes tips 10a, incline beams 10 and 10′ connected with each other, and a hollow body 30 having a square-column shape. The tips 10a are spaced at regular intervals and aligned collinearly. The incline beams 10 and 10′ are merged with the tips 10a and bent at angles of α° and 180-β°, respectively. The hollow body 30 is connected with at least one of the beams 10 and 10′ bent.

The incline beam 10 plays a role in distributing a stress concentration, resulting from an external force applied to the tips 10a, which is present at connecting portions between the incline beam 10 and the hollow body 30 and between the incline beam 10′ and the hollow body. Further, an elastic force is strengthened by the incline beam 10. Thus, an overdrive (OD) may be obtained readily.

As illustrated in (b) of FIG. 19, when the vertical-type electric contactor is pressurized by a predetermined external force, a top surface of a test pad is scratched to remove an oxide layer while at least one of the tips 10a moves to an outer side of a test pad from an inner side thereof. Thus, a test is readily conducted. When the external force is not applied, the original positions of the tips 10a are restored.

### Embodiment 5

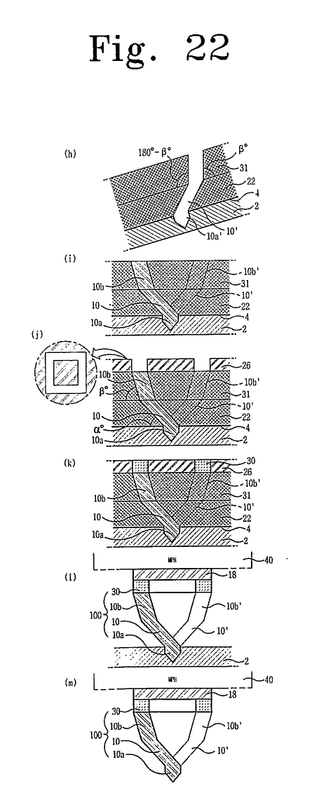

A method for fabricating a vertical-type electric contactor having a hollow body according to a fourth embodiment of the present invention will now be described with reference to FIG. 21 and FIG. 22. The same elements designated by the same numerals as in the first embodiment have the same functions and operations and will not be described in further detail.

Formation of a space in which first incline beams 10 and 10′ are formed, illustrated in (a) through (f) of FIG. 21, is done by the same steps as described with reference to (a) of FIG. 17 through (e) of FIG. 18 and will not be described in further detail.

As illustrated in (g) of FIG. 21, a first passivation pattern 31 is formed on a sacrificial substrate 2 where a space is offered for forming the first incline beams 10 and 10′. The first passivation pattern 31 has an incline beam section pattern. The sacrificial substrate 2 is loaded on a wafer chuck of a typical inclined exposure apparatus. While the loaded sacrificial substrate 2 is inclined so that an incline beam has an angle of β° based on a top surface of the sacrificial substrate 2, exposing and developing processes are carried out to offer a space for forming a second incline beam 10b by means of a subsequent filling process using a metal material. The first passivation pattern 31 is disposed to form a second incline beam 10b having an angle of β° based on the top surface of the sacrificial substrate 2 and another second incline beam 10b′ having an angle of 240-β°.

As illustrated in (h) of FIG. 22, another second incline beam is formed to be spaced apart from the second incline beam. While the sacrificial substrate 2 is inclined so that the incline beam has an angle of 180-β°, exposing and developing processes are carried out to offer a space for forming a second incline beam by means of a subsequent filling process using a metal material.

As illustrated in (i) of FIG. 22, a space for forming incline beams 10, 10′, 10b, and 10b′ opened by first and second passivation patterns 22 and 31 and a trench for forming a tip 10a are filled with a conductive material by means of a plating process to form incline beams 10, 10′, 10b, and 10b′ which have angles of α°, 180-α°, β°, and 180-β°, respectively. The incline beams 10, 10′, 10b, and 10b′ are bent to be connected with the respective tips 10a.

As illustrated in (j) of FIG. 22, a third passivation pattern 26 is formed on the sacrificial substrate 2. The third passivation pattern 26 has a section shape of a hollow body, i.e., opens end top surfaces of the second incline beams 10b and 10b′. Thus, a space is offered for forming a hollow body.

As illustrated in (k) of FIG. 22, the space offered by the third passivation pattern 26 is filled with a conductive material by means of a plating process. Afterwards, a planarization process is carried tout to form a hollow body 30. The planarization process has been described previously and will not be described in further detail. Also, alternative method for fabricating the hollow body 30 has been described previously and will not be described in further detail. The hollow body 30 may have various hollow column shapes such as the square-column shape, the cylinder shape, and the triangle-column shape according to manufacturers. Alternatively, a body having the inner-filled column shape may be formed instead of the hollow body 16.

As illustrated in (1) of FIG. 22, after removing the first, second, and third passivation patterns for forming incline beams, the hollow body 30 is bonded with a bump 18 formed on an MPH 40.

As illustrated in (m) of FIG. 22, the sacrificial substrate 2 including the hollow body 30 bonded with the bump 18 is removed by means of a wet etch process to open the tip 10a. Thus, an electric contactor is fabricated which includes the tip 10a and the incline beams 10, 10′, 10b, and 10b′.

The angles α° and β° have the relationship as follow:

0°<α°<β°<90°

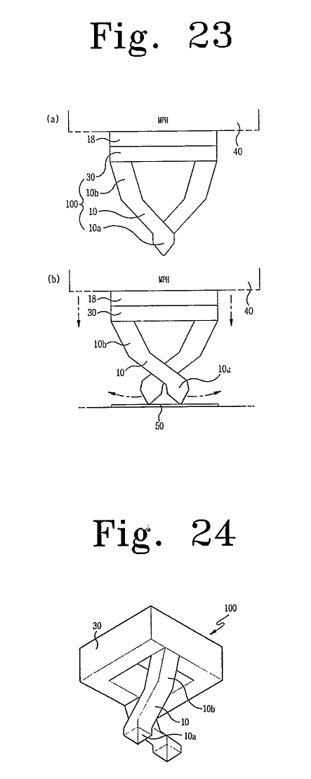

As illustrated in (a) of FIG. 23 and FIG. 24, the vertical-type electric contactor fabricated by the method described with reference to FIG. 21 and FIG. 22 includes one or more tips 10a spaced apart from each other to be aligned collinearly, first incline beams 10 and 10′, and one or more second incline beams 10b and 10b′, and a hollow body 30 having a square-column shape. The first incline beams 10 and 10′ are connected with each other and bent to have an angle of α° based on a top surface of the tip 10a, respectively. The second incline beams 10b and 10b′ are connected with each other and bent to have an angle of α° based on top surfaces of the first incline beams 10 and 10′, respectively. The second incline beams 10b and 10b′ are disposed at the hollow body 30.

The incline beams 10, 10′, 10b, and 10b′ constitute a bent beam. The bent beam distributes a stress concentration resulting from an external force applied to the tip 10a, and an elastic force is strengthened. Therefore, a lifespan of an electric contactor may be extended and an overdrive (OD) may be obtained readily.

As illustrated in (b) of FIG. 23, when a vertical-type electric contactor including such one or more incline beams is pressurized by a predetermined external force, a top surface of a test pad is scratched to remove an oxide layer while at least one tip 10a moves to the outer side of the test pad from the inner side thereof. Thus, a test is readily conducted. When the external force is not applied, the original positions of the tips 10a are restored.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various modifications as are suited to the particular use contemplated. It is intended that the scope of the invention be defined by the claims appended hereto and their equivalents.

### INDUSTRIAL APPLICABILITY

An electric contactor according to the present invention can be applied to probe cards for electric test of semiconductor devices.

1. A method for fabricating a vertical-type electric contactor, comprising:
(a) forming a first passivation pattern on a sacrificial substrate for forming at least one tip;
(b) performing an etch process, using the first passivation pattern as an etch mask, to form a trench in the sacrificial substrate;
(c) removing the first passivation pattern and forming a second passivation pattern on the sacrificial substrate to offer a space for forming a support beam, wherein the tip is merged with one end of the support beam;
(d) filling the trench and the space with a conductive material to form a tip and a support beam;
(e) forming a third passivation pattern on a sacrificial substrate including the tip and the support beam to offer a space for forming a hollow body;
(f) filling the space offered by the third passivation pattern with a conductive material to form a hollow body;
(g) bonding the hollow body with a bump formed on a micro-probe head (MPH); and
(h) removing the sacrificial substrate to open a tip of an electric contactor.

2. The method as recited in claim 1, wherein the trench is formed in the sacrificial substrate to collinearly define tips spaced by a predetermined distance.

3. The method as recited in claim 1, further comprising between the (c) and (d):
(c-1) forming a fourth passivation pattern on the sacrificial substrate to offer a space for forming a connecting beam vertically connected with the support beam; and
(c-2) filling the space offered by the fourth passivation pattern with a conductive material to form the connecting beam.

4. The method as recited in claim 3, wherein the support beams as well as tips are spaced by a predetermined distance to face each other and the respective tips of the support beams are extended to the end of a facing support beam.

5. The method as recited in claim 1, wherein in the (e), the third passivation pattern offers a space for connecting both ends of the support beam with the inner side end of the hollow body.

6. The method as recited in claim 1, further comprising:
after forming a passivation pattern on a sacrificial substrate where the tip is formed, performing exposing and developing processes while the sacrificial substrate is inclined at a predetermined angle to offer a space for forming a first incline beam connected with the tip at an angle of α°; and
filling the space with a conductive material to form a first incline beam.

7. The method as recited in claim 6, wherein the angle α° ranges from zero degree to 90 degrees (0°<α°<90°).

8. The method as recited in claim 6, further comprising:
after forming a passivation pattern for forming a second incline beam on a sacrificial substrate where the first incline beam is formed, performing exposing and developing processes while the sacrificial substrate is inclined at a predetermined angle to offer a space for forming a second incline beam connected with the first incline beam at an angle of β°; and
filling the space with a conductive material to form a second incline beam.

9. The method as recited in claim 6, wherein the angle β° ranges from α° to 90 degrees (0°<α°<β°<90°).

10. A method for fabricating a vertical-type electric contactor, comprising:
(a) forming a first passivation pattern on a sacrificial substrate for forming at least one tip;
(b) performing an etch process, using the first passivation pattern as an etch mask, to form a trench in the sacrificial substrate;
(c) removing the first passivation pattern and forming a second passivation pattern on the sacrificial substrate to offer a space for forming a support beam, wherein the tip is merged with one end of the support beam;
(d) filling the trench and the space offered by the second passivation pattern with a conductive material to form a tip and a support beam;
(e) forming a third passivation pattern on a micro-probe head (MPH) to offer a space for forming a bump;
(f) filling the space offered by the third passivation pattern with a conductive material to form a bump;
(g) forming a fourth passivation pattern on the MPH including the bump to offer a space for forming a hollow body;
(h) filling the space offered by the fourth passivation pattern with a conductive material to form a hollow body;
(i) bonding the support beam with the hollow body; and
(j) removing the sacrificial substrate to open a tip of an electric contactor.

11. The method as recited in claim 10, wherein the trench is formed in the sacrificial substrate to collinearly form tips spaced by a predetermined distance.

12. The method as recited in claim 10, further comprising between the (h) and (i):
(h-1) forming a passivation pattern on an MPH where the hollow body is formed to offer a space for forming a connecting beam vertically connected with the hollow body;
(h-2) filling the space offered by the passivation pattern with a conductive material to form a connecting beam; and
(h-3) bonding the support beam with the connecting beam.

13. The method as recited in claim 12, wherein the tips merged with the support beam are spaced by a predetermined distance to face each other and the respective tips of the support beams are extended to the end of a facing support beam.

14. The method as recited in claim 10, wherein in the (i), wherein the support beam is bonded to connect its both ends with an inner side end of the hollow body.

15. A vertical-type electric contactor comprising:
a micro-probe head (MPH) including at least one connecting terminal and interconnection for receiving an external signal;
a bump disposed on the connecting terminal of the MPH;
a column-shaped body vertically bonded with the bump;
at least one support beam spaced apart from an opposite surface of the bottom end of the body; and
a tip merged with the support beam.

16. The vertical-type electric contactor as recited in claim 15, wherein the body is a hollow body.

17. The vertical-type electric contactor as recited in claim 16, wherein the body has a square-column shape and the support beam is disposed at a corner of the body having the square-column shape.

18. The vertical-type electric contactor as recited in claim 15, wherein the one or more tips are spaced by a predetermined distance and aligned collinearly.

19. The vertical-type electric contactor as recited in claim 16, further comprising:
a connecting beam disposed between the hollow body and the support beam and vertically connected with the support beam.

20. The vertical-type electric contactor as recited in claim 19, wherein the tips merged with the support beams are spaced by a predetermined distance to face each other and the respective tips of the support beams are extended to the end of a facing support beam.

21. The vertical-type electric contactor as recited in claim 16, wherein both ends of the support beam are connected with an inner side end of the hollow body.

22. The vertical-type electric contactor as recited in claim 15, further comprising:
a first incline beam having one side end connected with the tip at an angle of α° and the other side end connected with the hollow body at an angle of β°.

23. The vertical-type electric contactor as recited in claim 22, wherein the angle α° ranges from zero degree to 90 degrees (0°<α°<90°).

24. The vertical-type electric contactor as recited in claim 15, further comprising:
a second incline beam having one side end bent to be connected with one side end of a first incline beam having the other side end connected with the tip at an angle of α° and having the other side end connected with the hollow body at an angle of β°.

25. The vertical-type electric contactor as recited in claim 24, wherein the angle β° ranges from α° to 90 degrees (0°<α°<β°<90°).
